(19) United States
(12) Patent Application Publication
(10) Pub. No.: US 2026/0187304 A1
(43) Pub. Date: Jul. 2, 2026

(54) METHODS AND APPARATUS FOR GENERATING PHYSICAL LAYOUTS OF AUTOMATED LABORATORY DIAGNOSTIC SYSTEMS

(71) Applicant: Siemens Healthcare Diagnostics Inc., Tarrytown, NY (US)

(72) Inventors: Rayal Prasad, Princeton, NJ (US); Mark Edwards, Armonk, NY (US); Ankur Kapoor, Plainsboro, NJ (US)

(73) Assignee: Siemens Healthcare Diagnostics Inc., Tarrytown, NY (US)

(21) Appl. No.: 19/130,361

(22) PCT Filed: Nov. 29, 2023
(86) PCT No.: PCT/US2023/081514

§ 371 Date: May 15, 2025

Related U.S. Application Data
(60) Provisional application No. 63/385,400, filed on Nov. 29, 2022.

(51) Int. Cl. G06F 30/17

(52) U.S. Cl. CPC G06F 30/17

(57) ABSTRACT

Systems and methods of generating an optimal physical layout of an automated laboratory diagnostic system may include generating a tentative physical layout based on laboratory requirements, simulating sample testing in the automated laboratory diagnostic system using the tentative physical layout, repeating the generating of a tentative physical layout in response to the simulating not meeting one or more laboratory objectives, and outputting a final physical layout in response to the simulating meeting the laboratory requirements and the one or more laboratory objectives. Numerous other aspects are provided.

### CROSS REFERENCE TO RELATED APPLICATION

This application claims the benefit of U.S. Provisional Patent Application No. 63/385,400, entitled “METHODS AND APPARATUS FOR GENERATING PHYSICAL LAYOUTS OF AUTOMATED LABORATORY DIAGNOSTIC SYSTEMS” filed Nov. 29, 2022, the disclosure of which is hereby incorporated by reference in its entirety for all purposes.

### FIELD

This disclosure relates to generating physical layouts of automated laboratory diagnostic systems.

### BACKGROUND

Automated laboratory diagnostic systems, such as, e.g., the Atellica® Solution commercially available from Siemens Medical Solutions USA, Inc., headquartered in Malvern, Pennsylvania, United States, may be used to conduct clinical chemistry/assay testing or analysis of a bio-fluid sample such as urine, blood serum, blood plasma, interstitial liquid, cerebrospinal liquids, or the like to identify an analyte or other constituent therein. Such systems may be designed to process large numbers of samples concurrently. For example, in large-scale reference labs where multiple such systems may be connected by a lab automation network (e.g., such as the Aptio® Automation FlexLab also available from Siemens), the number of samples present on the system at any given time may number in the hundreds or even thousands. The samples may be contained in sample containers (e.g., blood collection tubes) that are transported on sample carriers through the automated laboratory diagnostic system. One or more reagents may be added to a bio-fluid sample, wherein a resulting assay or test reaction may generate various changes in the sample that may be detected and/or manipulated to determine a concentration of an analyte or other constituent present in the sample.

Automated laboratory diagnostic systems typically include the following: a plurality of sample carriers configured to receive therein sample containers containing bio-fluid samples to be analyzed; a plurality of modules for pre-processing, analyzing, and post-processing the bio-fluid samples; and a sample transport system that includes hardware such as a movable track configured to move the sample carriers throughout the automated laboratory diagnostic system.

The modules of automated laboratory diagnostic systems may perform automated analytical sample preparation and handling operations such as sorting, batch preparation, centrifuging of sample containers to separate sample constituents, cap removal to facilitate sample access, and the like. The modules may include, e.g., input/output sample handlers, centrifuges, quality check modules, decappers, heaters, aspirating/dispensing modules, and storage and/or refrigeration modules. The modules may also include various analyzers, such as, e.g., clinical chemistry analyzers, immunoassay analyzers, and molecular testing analyzers. Automated laboratory diagnostic systems may include a plurality of the same or similar types of modules to allow the system to efficiently process/analyze multiple samples in parallel and/or to have multiples of the same module configured differently (e.g., preloaded with different reagents) to perform a same type of analysis/test on different bio-fluid samples without having to reconfigure a module each time a different type of bio-fluid sample is tested/analyzed by that module.

Once an operator places a bio-fluid sample (contained in a sample container) into an input/output sample handler module of an automated laboratory diagnostic system, the sample container is automatically loaded into a sample carrier. The sample container may have a machine-readable label (e.g., a barcode label) thereon that is read by the system. The label may indicate the test(s)/analysis(es) to be performed on the sample and may include, e.g., an accession number that may be correlated to demographic information stored in a hospital's Laboratory Information System (LIS) along with test orders and/or other information. In response to the information read on the sample container label, the system creates an instruction list that specifies a particular sequence of destinations (e.g., modules) based on each testing or analysis process desired. These destinations may be in a particular sequence (e.g., the sample first visits a centrifuge module and then a decapper module) with specified time windows between destinations (e.g., the sample carrier may be scheduled to arrive at an aspiration/dispensing module within a 90-second time window from a previous decapper module). These time windows may help ensure that a sample is prepared and analyzed before it degrades or becomes unusable, after which any results obtained may not be reliable. An automated laboratory diagnostic system may automatically handle processing of many samples at the same time by automatically routing each of the sample containers loaded in a sample carrier via a sample transport system to one or more modules based on the instruction list.

Each automated laboratory diagnostic system may have a varied and unique set of system requirements, which may include configuration parameters and physical design constraints. An automated laboratory diagnostic system may also have various objectives, which may be prioritized, and related to, e.g., system performance, associated costs, and/or supply usage. Some of these requirements and objectives may include, e.g., the types of tests/analyses the system may perform, the types and numbers of modules to be included in the system, the number of samples to be processed per day, etc. Because of the sheer number of possible requirements and/or objectives, determining the optimal physical layout for a given system can be difficult. For some systems, the physical layout may be optimized for maximizing sample throughput or sample turn-around-time while for others minimizing reagent/calibration cost, the size of the system's physical footprint, or any combination thereof may be of primary concern. Determining the “optimal physical layout” is specific to both a system's requirements and objectives. Therefore, there is a need for methods and apparatus for determining an optimal physical layout of an automated laboratory diagnostic system based on a given set of system requirements and objectives.

### SUMMARY

According to a first aspect, a method of generating a physical layout of an automated laboratory diagnostic system includes receiving, at a processor executing layout generator software, laboratory requirements including sample tests to be performed, physical space constraints, and anticipated sample workload. The method also includes receiving, at the processor executing the layout generator software, one or more laboratory objectives, and identifying, via the processor executing the layout generator software, particular types of modules and redundancy thereof to be included in a tentative physical layout based on the laboratory requirements. The method further includes, via the processor executing the layout generator software, placing the particular modules in the tentative physical layout and connecting the particular modules placed in the tentative physical layout using a sample transport system based on the laboratory requirements to complete the tentative physical layout. The method still further includes simulating sample testing using the tentative physical layout, and repeating the identifying, the placing, and the connecting in response to the simulating not meeting the one or more laboratory objectives. The method also includes outputting, via a user interface coupled to the processor, a final physical layout in response to the simulating meeting the one or more laboratory objectives.

According to a second aspect, a system for generating a physical layout of an automated laboratory diagnostic system includes a computer including a processor, a memory, and a user interface, wherein layout generator software is stored in the memory. The processor, executing the layout generator software, is operative to receive (a) laboratory requirements including sample tests to be performed, physical space constraints, and anticipated sample workload, and (b) one or more laboratory objectives. The processor, executing the layout generator software, is also operative to identify particular types of modules and redundancy thereof to be included in a tentative physical layout based on the laboratory requirements. The processor, executing the layout generator software, is further operative to place the particular modules in the tentative physical layout and connect the particular modules placed in the tentative physical layout using a sample transport system based on the laboratory requirements to complete the tentative physical layout. The processor, executing the layout generator software, is still further operative to simulate sample testing using the tentative physical layout; repeat the identify, the place, and the connect in response to a simulation of a subset of the tests executed on the tentative physical layout not meeting the one or more laboratory objectives; and output via the user interface a final physical layout in response to a simulation meeting the one or more laboratory objectives.

According to a third aspect, a method of generating a physical layout of an automated laboratory diagnostic system includes, at a processor executing layout generator software, receiving a set of pre-defined physical layouts for the automated laboratory diagnostic system; receiving laboratory requirements including sample tests to be performed, physical space constraints, and anticipated sample workload; and receiving one or more laboratory objectives. The method also includes simulating sample testing using a physical layout of the set of the pre-defined physical layouts that includes all modules needed for performing the sample tests. The method further includes, in response to a previous simulation not meeting the laboratory requirements and the one or more laboratory objectives, repeating the simulating of the sample testing using a different physical layout of the set of the pre-defined physical layouts that includes all modules needed for performing the sample tests. The method still further includes outputting, via a user interface coupled to the processor, one of the pre-defined physical layouts in response to a simulation of the one pre-defined physical layout meeting the laboratory requirements and the one or more laboratory objectives.

According to a fourth aspect, a method of generating a physical layout of an automated laboratory diagnostic system is provided that includes receiving, at a processor executing layout generator software, a set of pre-defined physical layouts for the automated laboratory diagnostic system. The method also includes receiving, at the processor executing layout generator software, laboratory requirements including sample tests to be performed, physical space constraints, and anticipated sample workload. The method further includes receiving, at the processor executing layout generator software, one or more laboratory objectives. The method also includes selecting a physical layout of the set of predefined physical layouts that includes all modules needed for performing the sample tests. The method further includes simulating sample testing using the selected physical layout. The method also includes, if the laboratory requirements and the one or more laboratory objectives are not met, employing reinforcement learning or an evolutionary algorithm to select a different physical layout of the set of pre-defined physical layouts that includes all the modules needed for performing the sample tests and repeating the simulating. The method still further includes, if the laboratory requirements and the one or more laboratory objectives are met with one of the predefined physical layouts, outputting, via a user interface coupled to the processor, the one pre-defined physical layout.

Still other aspects, features, and advantages of this disclosure may be readily apparent from the following description and illustration of a number of example embodiments, including the best mode contemplated for carrying out the disclosure. This disclosure may also be capable of other and different embodiments, and its several details may be modified in various respects, all without departing from the scope of the disclosure.

### BRIEF DESCRIPTION OF THE DRAWINGS

The drawings, described below, are provided for illustrative purposes and are not necessarily drawn to scale. Accordingly, the drawings and descriptions are to be regarded as illustrative in nature, and not as restrictive. The drawings are not intended to limit the scope of the disclosure in any way.

FIGS. 1A to 1C illustrate plan views of three example physical layouts of automated laboratory diagnostic systems in accordance with one or more embodiments.

FIG. 2 illustrates an example automated laboratory diagnostic system capable of automatically processing multiple bio-fluid samples in accordance with one or more embodiments.

FIG. 3 illustrates a side view of a sample container that may include a separated sample with a serum or plasma portion in accordance with one or more embodiments.

FIG. 4 illustrates a side view of the sample container of FIG. 3 held in an upright orientation in a sample carrier that can be transported within the automated laboratory diagnostic system of FIG. 2 in accordance with one or more embodiments.

FIGS. 5A and 5B illustrate top and side views, respectively, of an example quality check module that may be used in an automated laboratory diagnostic system in accordance with one or more embodiments.

FIG. 6 illustrates a block diagram of a computer operative to generate a physical layout of an automated laboratory diagnostic system in accordance with one or more embodiments.

FIG. 7 illustrates a high-level operational diagram of layout generator software in accordance with one or more embodiments.

FIG. 8 illustrates an iterative process for generating a tentative physical layout by a layout program of the layout generator software of FIG. 7 in accordance with one or more embodiments.

FIGS. 9A, 9B, and 9C illustrate three example physical layouts generated by another embodiment of the layout program of the layout generator software of FIG. 7 in accordance with one or more embodiments.

FIG. 10 illustrates a set of pre-defined physical layouts for an automated laboratory diagnostic system in accordance with one or more embodiments.

FIG. 11 illustrates a flowchart of an example of an optimization process for optimizing a tentative physical layout in accordance with one or more embodiments.

FIG. 12 illustrates a flowchart of an alternative optimization process for optimizing a tentative physical layout in accordance with one or more embodiments.

FIG. 13 illustrates a flowchart of a method of generating a physical layout of an automated laboratory diagnostic system according to one or more embodiments.

FIG. 14 illustrates a flowchart of another method of generating a physical layout of an automated laboratory diagnostic system according to one or more embodiments.

FIG. 15 illustrates a flowchart of another method of generating a physical layout of an automated laboratory diagnostic system according to one or more embodiments.

### DETAILED DESCRIPTION

Independent of the grammatical term usage, individuals with male, female or other gender identities are included within the term.

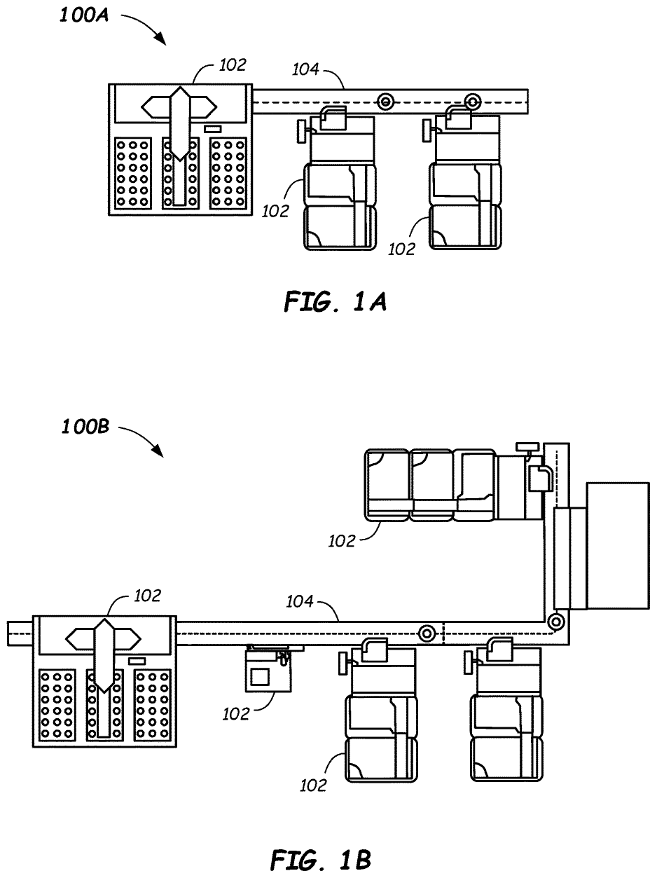

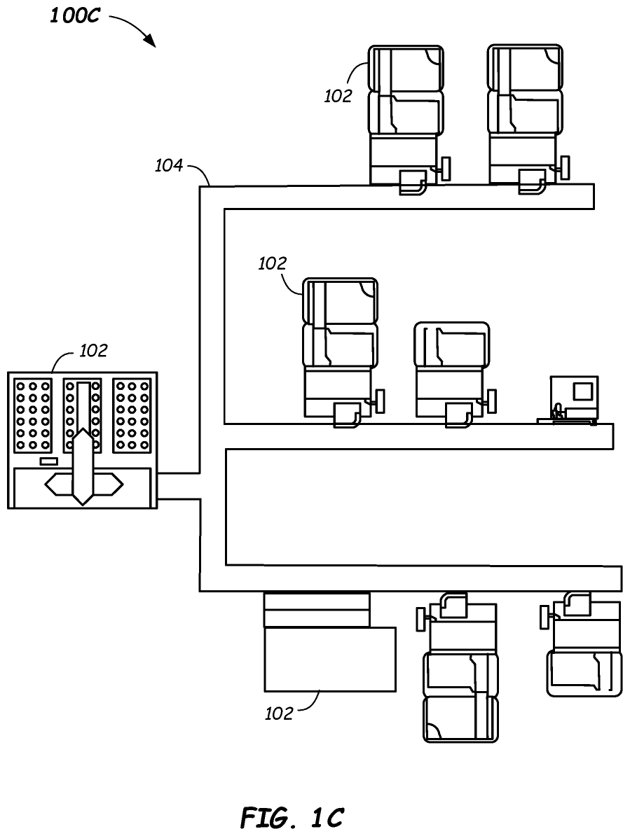

Embodiments described herein include methods and apparatus for generating optimized physical layouts for automated laboratory diagnostic systems and, in particular, for large automated laboratory diagnostic systems that process hundreds or even thousands of samples per day. As mentioned above, each system has its own unique sets of requirements and objectives, such as, e.g., the kinds of tests/analyses to be performed by the system, the types and numbers of modules to be included in the system, the available floor space within which the system is to be installed, an expected workload of the system, a desired sample turn-around-time, a desired sample throughput, a target purchase and/or operating cost of the system, etc. As shown by physical layouts 100A, 100B, and 100C of FIGS. 1A, 1B, and 1C, respectively, automated laboratory diagnostic systems can be configured in various ways based on the requirements and objectives of each system. Each of the systems represented by physical layouts 100A, 100B, and 100C includes various modules 102 (only a few labeled) connected to each other via a sample transport system 104. The modules 102 may perform, e.g., sample input/output loading, centrifugation, sample quality checking, sample characterization, decapping, aliquot preparation, clinical analysis or assaying, and sample or reagent storage/refrigeration.

Some of the factors to be considered when determining the physical layout of an automated laboratory diagnostic system include: floorplan details including available physical space and construction constraints (e.g., positions of immovable columns), power source location(s), physical user access to the system, etc.; assay/testing requirements; types of pre- and post-processing modules required; and various laboratory objectives specific to the system, such as, e.g., sample throughput (e.g., number of samples to be processed per day); sample turn-around-times, reagent replacement rates, load balancing of the modules, redundancy requirements, hardware costs, operating costs, etc.

Because many known automated laboratory diagnostic systems are modular in nature, an infinite number of physical layouts may potentially be possible for each set of requirements and objectives. To help simplify the physical layout process, some known systems provide a fixed set of predefined physical layouts. For example, one known system provider has 30 pre-defined physical layouts. However, even within a limited number of pre-defined physical layouts, determining which physical layout would be optimal for a particular system based on all the above-mentioned possible requirements and/or objectives is still a non-trivial task.

As an example, a physical layout may be determined by examining the operations and performances of existing physical layouts of other systems and deciding the best physical layout based on trial-and-error and/or rules created by very experienced operators, or in some cases, merely via intuition based primarily on the predicted/known testing requirements and objectives provided by a user. However, these processes are seldom exhaustive enough to lead to optimal results and may frequently result in physical layouts having more modules than necessary to meet certain objectives (e.g., throughput), which may thus inadvertently and/or unnecessarily increase costs related to the system itself, its operation, maintenance, calibration, etc.

In accordance with one or more embodiments provided herein, systems and methods are described below in connection with FIGS. 1A-15 that automatically generate a physical layout for an automated laboratory diagnostic system based on the system's requirements and objectives. The generated physical layout allows the system to perform desired tests/assays and achieve all of, or achieve as close as possible, its desired objectives while employing only the optimal number of resources (e.g., modules, transport system components, etc.). In some embodiments, layout generator software executing on a computer processor may start with a “blank canvas” (i.e., no pre-determined or pre-positioned system components or layout features) and generate a physical layout based on an automated laboratory diagnostic system's requirements and objectives (referred to hereinafter as a “blank canvas embodiment”). In other embodiments, the layout generator software executing on the computer processor may receive as input a set of predefined physical layouts for the automated laboratory diagnostic system along with the system's requirements and objectives and select one of the pre-defined physical layouts that best meets the system's requirements and objectives (referred to hereinafter as a “pre-defined layout embodiment”).

Embodiments of the layout generator software may include a Reinforcement Learning (RL) algorithm that receives as input the system's requirements and objectives. The RL algorithm processes the received inputs and then outputs an optimized physical layout of the system that can be used to custom fit an automated laboratory diagnostic system at a user's site. For example, in RL, an “agent” is trained to take “actions” in an “environment” (note that this terminology is known in the art). The agent uses a “policy” (which could be a neural network) to take in “observations” as inputs and outputs an action. In one embodiment, the observations may be the objectives determined via simulation of sample testing on an initially determined (tentative) physical layout, while the outputs may be actions such as placing a new module, rotating a previously placed module, and connecting the modules via components of a sample transport system (e.g., via track segments). RL also uses the concept of a “reward” to help guide the agent's learning—if an action is favorable, the learning setup associates that with a positive reward. Note that some RL methods deal with directly training a policy network while other value-based methods may be used as well.

The RL environment is where the agent's actions are evaluated. This may be done, as mentioned above, by running a simulation of a tentative physical layout of the automated laboratory diagnostic system. The environment may simulate a representative number of sample tests to be performed by the system using a physical layout generated by the agent (e.g., a layout program) and compare the simulation results with the objectives of the system. All these factors help shape the reward function, which may include objectives such as turn-around-time (TAT)/sample throughput. The reward function may be running a simulation of the worklist on the generated configuration and determine whether the objectives (which may be weighted according to priorities of the proposed system) have been met or not.

RL training happens iteratively, and agents are trained for many “episodes.” Each episode may start with a random set of sample tests/system requirements and objectives for which the agent iteratively generates a physical layout all while updating its weights using the reward function. An episode may be considered complete when the generated physical layout meets the requirements and objectives, or after a certain timeout (i.e., the agent is unable to generate a physical layout that meets all the requirements and objectives in a reasonable amount of time). Eventually, with enough training, the agent starts generating sufficiently satisfactory physical layouts in very few iterations (i.e., episode lengths reduce). At this point, the policy is fixed (e.g., a neural network or similar machine learning algorithm associated with the policy of the agent is fixed and weights/parameters are unchanged) and multiple iterations are run on a set of requirements and objectives until the layout generator software generates a satisfactory physical layout. This is equivalent to running just one episode of training except that no weight updates are made to the agent. Note that the “environment” used here is the same one used in training (i.e., a simulation program) and the same observations from the environment are used to feed into the RL agent. Examples of RL implementations are described in more detail further below.

Other embodiments of the layout generator software may additionally or alternatively include evolutionary algorithms (EAs). As is known, EAs are particularly well-suited for solving complex problems, such as generating physical layouts for automated laboratory diagnostic systems having complex requirements and objectives.

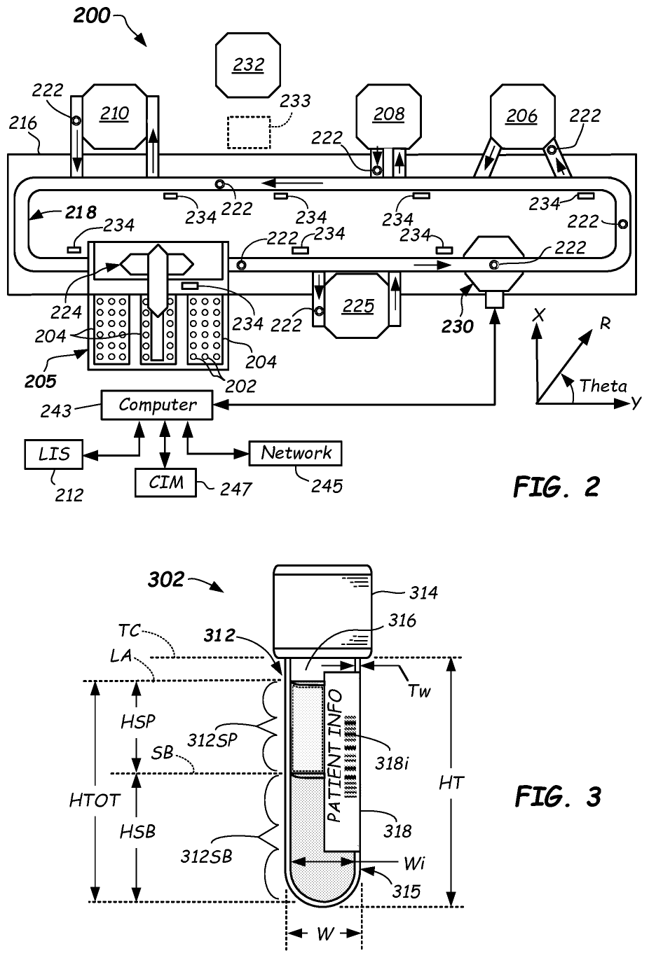

FIG. 2 illustrates an example physical layout of an automated laboratory diagnostic system 200 that is capable of automatically processing multiple sample containers 202 containing bio-fluid samples. The following description of the components and operation of system 200 is provided to illustrate the functional complexity and potentially large number of requirements and objectives that may be provided as input to the layout generator software for generating a physical layout of a system with comparable functionality and performance as system 200.

The sample containers 202 may be provided by a user and placed in one or more racks 204 at an input/output sample handler module 205 prior to transportation to, and analysis by, one or more analyzer modules (e.g., first analyzer module 206, second analyzer module 208, and/or third analyzer module 210) arranged about the system 200. More or fewer analyzer modules may be used in the system 200. The analyzer modules may be any combination of any number of clinical chemistry analyzers, assaying instruments, and/or the like. The term “analyzer” as used herein means a device used to analyze for chemistry or to assay for the presence, amount, or functional activity of a target entity (the analyte), such as DNA or RNA, for example. Analytes commonly tested for in clinical chemistry analyzers include enzymes, substrates, electrolytes, specific proteins, abused drugs, and therapeutic drugs. The sample containers 202 may be any suitably transparent or translucent containers, such as blood collection tubes, test tubes, sample cups, cuvettes, or other clear or opaque glass or plastic containers capable of containing and allowing imaging of a bio-fluid sample contained therein. The sample containers 202 may be varied in size and may have different cap colors and/or cap types.

Referring to FIG. 3, bio-fluid sample 312 may be provided to the system 200 in a sample container 302, which is an embodiment of sample containers 202 and may be a tube 315. Other sample container shapes and/or types may be used. The sample containers may be capped with caps 314. The caps 314 may be of different types and/or colors (e.g., red, royal blue, light blue, green, grey, tan, yellow, or color combinations), which may indicate what test each sample container 302 is used for, the type of additive (e.g., reagent) included therein, whether the container includes a gel separator, whether the sample is provided under a vacuum, or the like. Other colors may be used. In one or more embodiments, the cap type may be determined by a characterization method performed by system 200.

Each of the sample containers 302 may be provided with one or more labels 318 that may include identification information 318i (i.e., indicia) thereon, such as a barcode, alphabetic characters, numeric characters, or combinations thereof. Example identification information 318i may include or be associated with (e.g., through a Laboratory Information System (LIS) 212 database as shown in FIG. 2), patient information (e.g., name, date of birth, address, and/or other personal information), tests to be performed, time and date the sample was obtained, medical facility information, tracking and routing information, etc. Other information may also be included. The identification information 318i may be machine readable at various locations about the system 200.

The machine-readable information may be darker (e.g., black) than the label material (e.g., white paper) so that it can be readily imaged, for example. The identification information 318i may indicate, or may otherwise be correlated to, via the LIS 212 or other test ordering system, a patient's identification as well as tests to be performed on the sample 312. Such identification information 318i may be provided on the label 318, which may be adhered to or otherwise provided on an outside surface of the tube 315. As shown in FIG. 3, the label 318 may not extend all the way around the sample container 302 or all along a length of the sample container 302 such that from the particular lateral front viewpoint shown, some or a large part of a sample 312 (e.g., a serum or plasma portion 312SP, for example) is viewable (the part shown as dotted) and unobstructed by the label 318.

The sample 312 may include any fluid to be tested and/or analyzed (e.g., blood serum, blood plasma, urine, interstitial fluid, cerebrospinal fluid, or the like). In some embodiments, the sample 312 may include the serum or plasma portion 312SP and a settled blood portion 312SB contained within the tube 315. Air 316 may be provided above the serum and plasma portion 312SP and a line of demarcation between them is defined as the liquid-air interface (LA). The line of demarcation between the serum or plasma portion 312SP and the settled blood portion 312SB is defined as a serum-blood interface (SB). An interface between the air 316 and cap 314 is defined as a tube-cap interface (TC). The height of the tube (HT) is defined as a height from a bottom-most part of the tube 315 to a bottom of the cap 314 and may be used for determining tube size (tube height). A height of the serum or plasma portion 312SP is HSP and is defined as a height from a top of the serum or plasma portion 312SP at LA to a top of the settled blood portion 312SB at SB. A height of the settled blood portion 312SB is HSB and is defined as a height from the bottom of the settled blood portion 312SB to a top of the settled blood portion 312SB at SB. HTOT is a total height of the sample 312 and equals HSP plus HSB.

Returning to FIG. 2, system 200 may include a base 216 (e.g., a frame, floor, 4 other structure) upon which a track 218 may be mounted. The track 218 may be a railed track (e.g., a monorail or a multiple rail), a collection of conveyor belts, conveyor chains, moveable platforms, or any other suitable type of conveyance mechanism. Track 218 may be circular or any other suitable shape and may be a closed track (e.g., endless track) in some embodiments. Track 218 may, in operation, transport individual ones of the sample containers 202 via sample carriers 222 to various locations arranged about the track 218.

Sample carriers 222 may be passive, non-motored pucks that may be configured to carry a single sample container 202 on the track 218, or alternatively, may be automated including an onboard drive motor, such as a linear motor that is programmed or controlled to move about the track 218 and stop at pre-programmed locations. Other configurations of sample carrier 222 may be used.

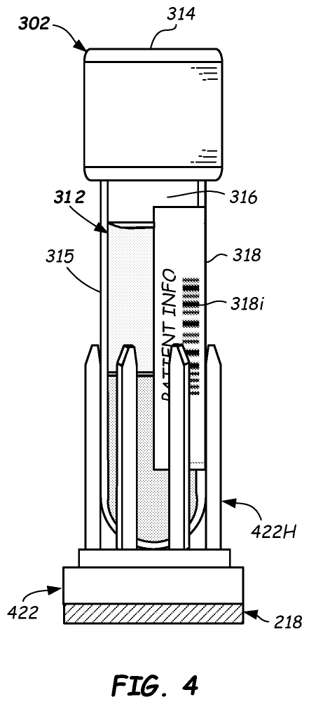

FIG. 4 illustrates a sample carrier 422, which is an embodiment of sample carriers 222 of FIG. 2. Sample carrier 422 may include a holder 422H configured to hold the sample container 302 in a defined upright position and orientation. The holder 422H may include a plurality of fingers or leaf springs that secure the sample container 302 to the sample carrier 422, wherein some may be moveable or flexible to accommodate different sizes (widths) of the sample containers 202/302. In some embodiments, sample carrier 422 may leave from the input/output sample handler module 205 (FIG. 2) after receiving a sample container 202/302 from the one or more racks 204. After pre-screening and/or analysis of the sample in a sample container 202/302 is complete, the sample carrier 422 may return to input/output sample handler module 205 to have the sample container 202/302 unloaded to the one or more racks 204 and then re-loaded with another sample container 202/302.

Returning to FIG. 2, a robot 224 may be provided at the input/output sample handler module 205 and may be configured to grasp the sample containers 202/302 from the one or more racks 204 and load the sample containers 202/302 onto the sample carriers 222/422, which may be on an input lane of the track 218 inside the input/output sample handler module 205. The robot 224 may also be configured to reload sample containers 202/302 from the sample carriers 222/422 to the one or more racks 204. The robot 224 may include one or more (e.g., at least two) robot arms or components capable of X (lateral) and Z (vertical—out of the page, as shown); Y and Z; X, Y, and Z; or r (radial) and theta (rotational) motion. The robot 224 may be a gantry robot, an articulated robot, an R-theta robot, or other suitable robot wherein the robot 224 may be equipped with robotic gripper fingers oriented, sized, and configured to pick up and place the sample containers 202/302.

Upon being loaded onto track 218, the sample carriers 222/422 carrying sample containers 202/302 may be transported to a first pre-processing module 225. For example, the first pre-processing module 225 may be an automated centrifuge configured to carry out fractionation of each sample 312. Carriers 222/422 carrying sample containers 202/302 may be diverted to the first pre-processing module 225 by an inflow lane or suitable robot. After being centrifuged, the sample containers 202/302 may exit on an outflow lane, or otherwise be removed by a robot, and continue along the track 218. In the depicted embodiment, the sample containers 202/302 in sample carriers 222/422 next may be transported to a quality check module 230.

The quality check module 230 is configured to pre-screen and carry out one or more characterization methods. For example, quality check module 230 may automatically determine a presence of, and optionally an extent or degree of an H, I, and/or L interferent contained in a sample 312 or whether the sample is normal (N). If found to contain none or effectively-low amounts of H, I, and/or L so as to be considered normal (N), the sample 312 may continue on the track 218 to be analyzed by the one or more analyzer modules (e.g., the first, second, and/or third analyzer modules 206, 208, and/or 210). Other pre-processing operations may be conducted on the samples 312 and/or sample containers 202/302. After analysis by the one or more analyzer modules 206, 208, and/or 210, the sample container 202/302 may be returned to the input/output sample handler module 205 for reloading to the one or more racks 204 or otherwise offloaded.

In some embodiments, in addition to detection of HILN, segmentation of the sample container 202/302 and sample 312 may be performed at the quality check module 230. From the segmentation data, post processing may be used for quantification of the sample 312 (e.g., determination of HSP, HSB, HTOT, and/or possibly a determination of the location of SB, LA and/or TC). In some embodiments, characterization of the physical attributes (e.g., size-height and width (or diameter) ) of the sample container 202/302 may take place at the quality check module 230. Such characterization may include determining HT and W, and possibly TC, and/or Wi. From this characterization, the size of the sample container 202/302 may be extracted. Moreover, in some embodiments, the quality check module 230 may also determine cap type, which may be used as a safety check and may indicate whether a wrong tube type has been used for the test or tests ordered.

In some embodiments, a remote module 232 may be provided in the system 200 that is not directly linked to the track 218. For instance, an independent robot 233 (shown dotted) may carry sample containers 202/302 containing samples 312 to the remote module 232 and return them after testing/pre-processing. Optionally, the sample containers 202/302 may be manually removed and returned. Remote module 232 may be used to test for certain constituents, such as a hemolysis level, or may be used for further processing, such as to lower a lipemia level through one or more additions and/or through additional processing, or to remove a clot, bubble, or foam, that is identified in the characterization at quality check module 230, for example. Other pre-screening using the HILN detection methods may optionally be performed at remote module 232.

Additional modules may be provided at one or more locations on or along the track 218. For example, the additional modules may include a de-capping module, aliquoting module, one or more additional quality check modules 230, and the like.

The system 200 may include a number of sensors 234 at one or more locations around the track 218. Sensors 234 may be used to detect locations of sample containers 202/302 on the track 218 by, e.g., reading the identification information 218i, or like information (not shown) provided on each sample carrier 222/422. Any suitable means for tracking the location of sample carriers 222/422 and/or sample containers 202/302 may be used, such as proximity sensors. All of the sensors 234 may interface with a computer 243, such that the location of each sample carrier 222/422 and/or sample container 202/302 along the track 218 may be known at all times.

The pre-processing module 225 and the analyzer modules 206, 208, and 210 may be equipped with robotic mechanisms and/or inflow lanes configured to remove sample carriers 222/422 and/or sample container 202/302 from the track 218, and with robotic mechanisms and/or outflow lanes configured to return carriers 222/422 and/or sample container 202/302 to the track 218.

The system 200 may be controlled by the computer 243, which may be a microprocessor-based central processing unit CPU or other suitable controller having a suitable memory and suitable electronics and drivers for operating the various system components. The computer 243 may be housed as part of, or separate from, the base 216 of the system 200. The computer 243 may control movement of the carriers 222/422 to and from the input/output sample handler module 205, motion about the track 218, motion to and from the first pre-processing module 225 as well as operation of the first pre-processing module 225 (e.g., centrifuge), motion to and from the quality check module 230 as well as operation of the quality check module 230, and motion to and from each analyzer module 206, 208, and 210. In some embodiments, the operation of each analyzer module 206, 208, and 210 for carrying out the various types of testing (e.g., assay or clinical chemistry) may be carried out by a local workstation computer at each analyzer module 206, 208, and 210 that is in digital communication with computer 243, such as through a network 245 such as a local area network (LAN) or wireless area network (WAN) or other suitable communication network. Optionally, the operation of some or all of the aforementioned analyzer modules 206, 208, and 210 may be provided by computer 243.

The computer 243 may control the system 200 according to software, firmware, and/or hardware commands or circuits such as those used on the Dimension@ clinical chemistry analyzer sold by Siemens Medical Solutions USA, Inc., headquartered in Malvern, Pennsylvania, United States. Other suitable systems for controlling the system 200 may be used. In some embodiments, the control of the quality check module 230 may also be provided by the computer 243 or another suitable computer in accordance with the embodiments described herein.

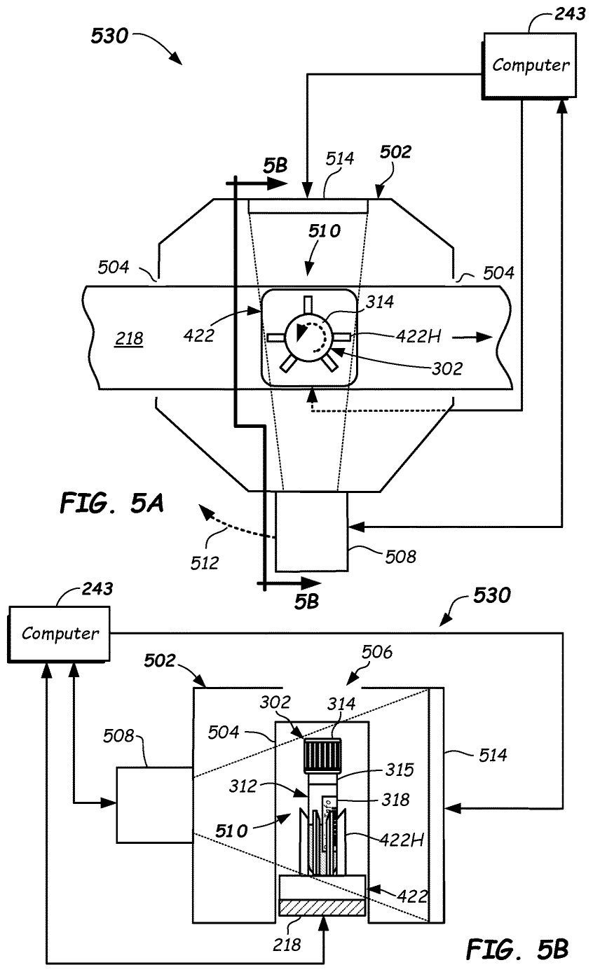

The computer 243 can also be used to control image processing and the characterization methods described herein in connection with FIGS. 5A-B (see below). The computer 243 may include a CPU or GPU, sufficient processing capability and RAM, and suitable storage, for example. In one example, the computer 243 may be a multi-processor-equipped PC with one or more GPUs, 8 GB RAM or more, and a Terabyte or more of storage. In another example, the computer 243 may be a GPU-equipped PC, or optionally a CPU-equipped PC operated in a parallelized mode. A Math Kernel Library (MKL) may be used as well, 8 GB RAM or more, and suitable storage.

In some embodiments, system 200 may include a computer interface module (CIM) 247 that allows a user to easily and quickly access a variety of control and status display screens. These control and status display screens may display and provide control of some or all aspects of plurality of interrelated automated devices used for preparation, pre-screening, and analysis of samples 312. The CIM 247 may be employed to provide information about the operational status of a plurality of interrelated automated devices as well as information describing the location of any sample 312 and a status of pre-screening and test(s) to be performed on, or being performed on, the sample 312. The CIM 247 is thus adapted to facilitate interactions between an operator and the system 200. The CIM 247 may include, for example, a display screen operative to display a menu including icons, scroll bars, boxes, and/or buttons through which the operator may interface with the system 200. The menu may comprise a number of functional elements programmed to display and/or operate functional aspects of the automated laboratory diagnostic system 200.

FIGS. 5A and 5B illustrate a quality check module 530, which is an embodiment of the quality check module 230 and is configured to carry out the functions described above and below. Quality check module 530 may be configured with programming instructions that, when executed by computer 243, perform a sample pre-screen to ensure the validity of tests to be conducted on the sample 312 contained in a sample container 202/302. For example, quality check module 530 may pre-screen for container material, label condition, sample container orientation, a presence of, and optionally, a degree of, a sample interferent (e.g., H, I, and/or L) in a sample 312 (e.g., in a serum or plasma portion 312SP thereof) prior to analysis by one or more of the analyzer modules 206, 208, and 210, and/or the like. Pre-screening in this manner allows for additional processing, additional quantification or characterization, and/or discarding and/or redrawing of a sample 312 without wasting valuable analyzer resources or possibly having the presence of an interferent adversely affect the veracity of the test results. Further, pre-screening may, in some respects, provide improved characterization of future samples 312.

In addition to interferent detection, other detection methods may be performed on the sample 312 contained in a sample container 202/302 at the quality check module 530. For example, a method may be carried out at the quality check module 530 to provide segmentation data. The segmentation data may be used in a post-imaging step to quantify the sample 312, e.g., to determine certain physical dimensional characteristics of the sample 312, such as the locations of LA and/or SB, and/or a determination of HSP, HSB, HT, Wi, and/or HTOT. Quantification may also involve estimating, e.g., a volume of the serum or plasma portion (VSP) and/or a volume of the settled blood portion (VSB) based upon quantification of the inner width Wi. Furthermore, the quality check module 530 may be used to quantify geometry of the sample container 202/302, i.e., quantify certain physical dimensional characteristics of the sample container 202/302, such as the location of TC, HT, and/or W or Wi of the sample container 202/302. Other quantifiable geometrical features may also be determined.

Quality check module 530 may include a housing 502 that may at least partially surround or cover the track 218 to minimize outside lighting influences. The sample container 202/302 may be located inside the housing 502 at an imaging location 510 during the image-taking sequences. Housing 502 may include one or more doors 504 to allow the carriers 222/422 to enter and/or exit from the housing 502. In some embodiments, the ceiling may include an opening 506 (FIG. 5B) to allow a sample container 202/302 to be loaded into the carrier 222/422 from above by a robot that may include moveable robot fingers. Quality check module 530 may also include an image capture device 508, which may be a camera, coupled to and controlled by the computer 243. Quality check module 502 may further include a back panel 514 positioned opposite image capture device 508 with a sample container 302 situated therebetween at imaging location 510. Back panel 514 is coupled to and controlled by the computer 243 and may provide a suitable and/or changeable background or backlighting. Image capture device 508 and back panel 514 may be rotatable about imaging location 510 as indicated by arrow 512. Image capture device 508 may be used to capture images from different angles of the sample container 302 and/or a bio-fluid sample 312 contained therein. The images thereof may be analyzed by computer 234 executing, e.g., an artificial intelligence algorithm, to perform an HILN determination and/or container/sample segmentation(s) as described above.

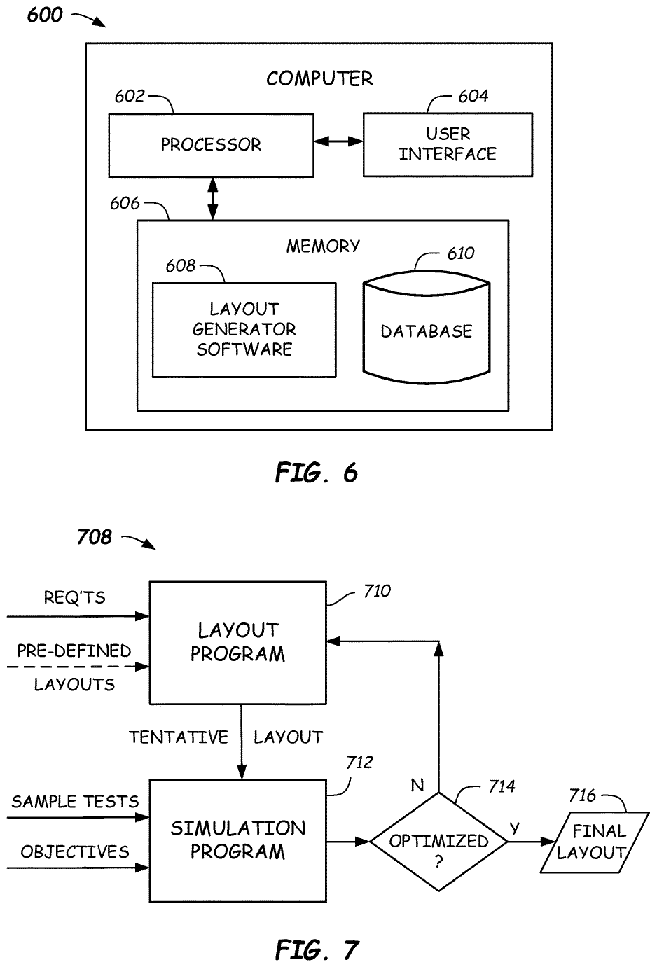

FIG. 6 illustrates a computer 600 operative to generate a physical layout of an automated laboratory diagnostic system based on the system's requirements (e.g., tests/analyses to be performed, available floor space, workload, etc.) and objectives (e.g., performance and/or costs) according to one or more embodiments. Computer 600 includes a processor 602, a user interface 604, and a memory 606. Memory 606 includes layout generator software 608 and a database 610 stored therein. In some embodiments, database 610 may be remote from and coupled to the computer 600. The layout generator software 608 is executable by the processor 602, and the database 610 contains data about modules and sample transport system components that may be included in a physical layout of an automated laboratory diagnostic system. The data stored in the database for each module may indicate the module's function(s), dimensions, footprint area and/or shape, execution time per sample per function, locations for interacting with/connecting to the sample transport system, and other module specifications and features relevant to its operation and performance and to layout generation. The data stored in the database for the sample transport system may indicate each type and configuration of track segment (e.g., straight segments, curved segments, three-way and four-way switch segments, etc.), dimensions thereof, sample carrier transport speeds there through, related track hardware (e.g., motors, track sensors, sample container robot handlers, etc.), and other components and specifications relevant to connecting the modules and transporting the sample carriers and to layout generation. The user interface 604 includes any device(s) and/or component(s) suitable for inputting a system's requirements and objectives and, in some embodiments, data representing a set of pre-defined physical layouts (described in more detail below) and for outputting a final physical layout that can be used to configure an automated laboratory diagnostic system for installation at a user's site.

FIG. 7 illustrates a high-level overview of layout generator software 708 according to one or more embodiments. Layout generator software 708, which is an embodiment of layout generator software 608, includes a layout program 710 and a simulation program 712, each executable by the processor 602 of computer 600 (or by separate processors and/or computer systems that may share information). In the blank canvas embodiments, layout program 710 receives requirements of the proposed system as input, processes the system requirements, generates a tentative physical layout from a “blank canvas” (i.e., no pre-determined or pre-positioned system components or layout features) based on the system requirements, and outputs the tentative physical layout.

The system requirements may include, e.g., a list of pre-processing tasks, tests/analyses, and post-processing tasks to be performed; the types of samples to be received; expected workload (e.g., a maximum number of samples to be handled concurrently by the system); physical constraints such as available floor space in terms of area and shape (e.g., rectangular, square, L-shaped, J-shaped, etc.), fixed structures within the floor space such as columns, walls, etc.; power source location(s); minimum space requirements for user access to the modules; etc.

The system requirements may additionally or alternatively include environmental criteria. For example, automated laboratory diagnostic systems may need to be maintained within certain temperature and humidity limits. Thus, system requirements may include power usage limits and heat management (e.g., too many modules sharing a power supply may generate excess heat, etc.). Adequate lighting conditions and/or vibration limits may also be considered system requirements.

The system requirements may additionally or alternatively include human factors such as biosafety and biosecurity practices because the proposed system will process biological samples. For example, if the proposed system is to handle samples that may test positive for highly contagious diseases such as HIV or COVID-19, the physical layout may need to include safety features (e.g., break rooms, isolated areas, additional sterilization modules, etc.). Furthermore, because some areas of the system may have more frequent human interaction than others (e.g., at input/output sample handler modules), additional constraints such as optimizing the locations of the input/output sample handler modules with respect to system entrances/exist to minimize expected foot traffic may be included as system requirements. For example, a “floor heatmap” (indicating high foot traffic) may be used as an input if personnel frequent only certain parts of the system.

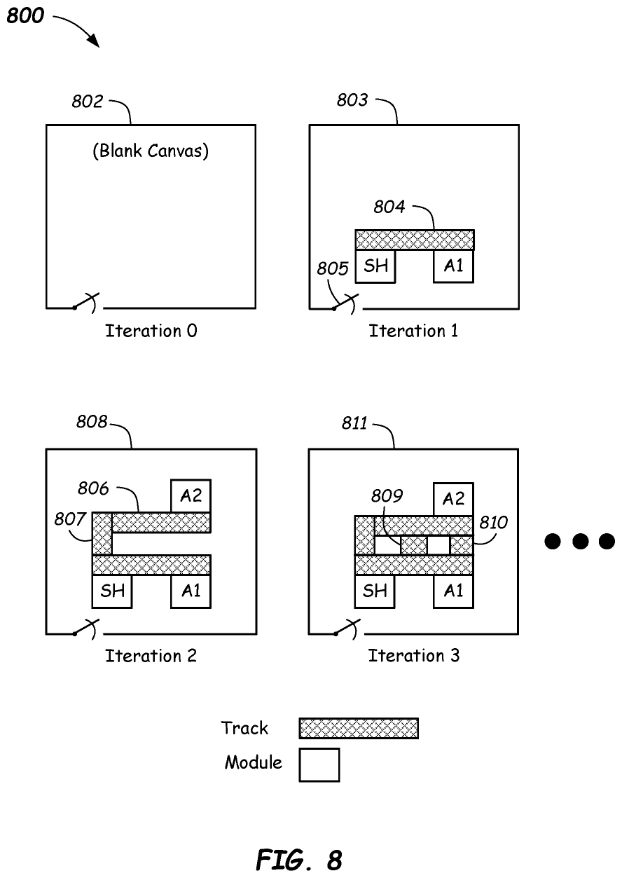

FIG. 8 illustrates a simple example of an embodiment of the layout program 710 that may employ an RL algorithm to iteratively generate a tentative physical layout for an automated laboratory diagnostic system. In some embodiments, an RL agent may start with a “blank canvas” (as shown by tentative physical layout 802 at Iteration 0) and may have the following action space: place a new module (e.g., an input/output sample handler, a quality check module, an aspiration/dispensing module; a clinical chemistry analyzer, an immunoassay analyzer, etc.); rotate/translate an existing module as needed; place a new sample transport system track segment (e.g., straight, curved, or intersection/switch in a specific orientation) to connect the module(s); and repeat until the system requirements are met.

In the example of FIG. 8, iterative generation of a tentative physical layout may be based on the following system requirements: tests/analyses to be performed, available floor space configuration, workload, and minimal foot traffic to the system. The tests/analyses to be performed may be specified as, e.g., analyte identification in two different types of bio-fluids. The available floor space configuration may be specified in terms of area (e.g., square footage) and/or dimensions/shape (e.g., square), represented by tentative physical layout 802 at Iteration 0 (i.e., the “blank canvas”). The workload may specify the maximum number of samples that can be handled safely in the system concurrently with little to no risk of colliding into each other. The layout program 710 processes the inputs, accesses the database 610 as needed, and determines the specific modules needed, how many of each module may be needed, how each module may be loaded with supplies (such as reagents, cuvettes, probes, etc.) and configured, and how the modules may be positioned and connected via the sample transport system (e.g., the track connections between the modules).

In particular, as shown by a tentative physical layout 803 at Iteration 1, the layout program 710 may determine that an input/output sample handler SH and an analyzer module A1 are needed and may place the SH, A1, and a track section 804. The layout program 710 may place the SH near a system entrance 805 to minimize foot traffic into and out of the system (provided the system entrance 805 had been indicated in the available floor space configuration provided as an input). The layout program 710 may also determine that an identical analyzer module A2 may also be needed to perform the analyte identifications of the two different types of bio-fluids, wherein each module may be configured and/or loaded differently (e.g., with different reagents) to perform the analyte identification of a respective bio-fluid sample. The layout program 710 may then place module A2 and track segments 806 and 807 as shown in a tentative layout 808 at Iteration 2. The layout program 710 may further determine that additional track segments 809 and 810 are needed to meet the required workload (i.e., the number of samples that can be handled safely in the system concurrently with little to no risk of colliding into each other) and may place track segments 809 and 810 as shown in tentative layout 811 at Iteration 3. The layout program 710 may iteratively continue after Iteration 3 to add pre- and post-processing modules as required to complete the tentative physical layout. As described in more detail further below, the tentative physical layout may then be simulated by simulation program 712 to determine whether the tentative physical layout meets the system objectives (e.g., sample throughput and/or sample turn-around-time) that have been input to the simulation program 712.

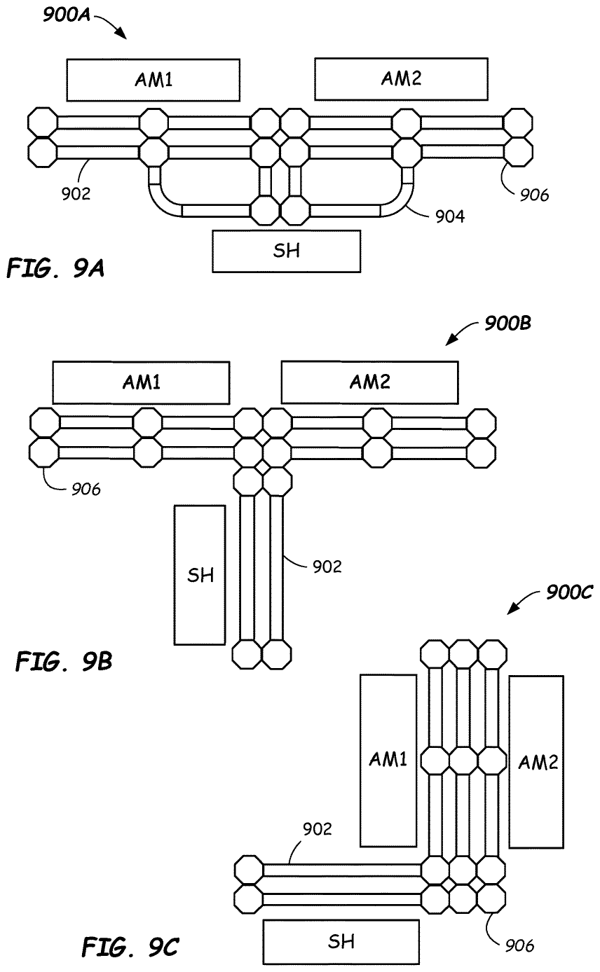

FIGS. 9A, 9B, and 9C illustrate an example of another embodiment of the layout program 710, wherein more than one tentative physical layout may be generated and output by the layout program 710 for a same set of requirements. The layout generator 710 may, in some embodiments, again employ an RL algorithm. In the example of FIGS. 9A-C, the layout program 710 may determine that an input/output sample handler (SH) and two analyzer modules AM1 and AM2 are needed to meet the input system requirements. Starting again with a “blank canvas,” the layout program 710 may generate three tentative physical layouts 900A, 900B, and 900C that each meets the system requirements. As shown, each layout includes modules SH, AM1, and AM2 and various track segments connecting the modules SH, AM1, and AM2 (only a few track segments labeled; see, e.g., straight track segments 902, curved track segments 904, and intersection/switch track segments 906). As described in more detail further below, each of the tentative physical layouts 900A, 900B, and 900C may be simulated by simulation program 712 to determine which one, if any, best meets system objectives (e.g., sample throughput and/or sample turn-around-time) that have been input to the simulation program 712.

Returning to FIG. 7, the layout program 710 may, in some embodiments, also receive as input a set of pre-defined physical layouts in addition to the system requirements. The set of pre-defined physical layouts may be provided by a manufacturer of automated laboratory diagnostic systems. The layout program 710 may process the system requirements and the set of pre-defined physical layouts and, in some embodiments, select and output a least complex or other physical layout from the received set of pre-defined physical layouts that meets the system requirements. The selected pre-defined physical layout is considered a tentative physical layout at this stage.

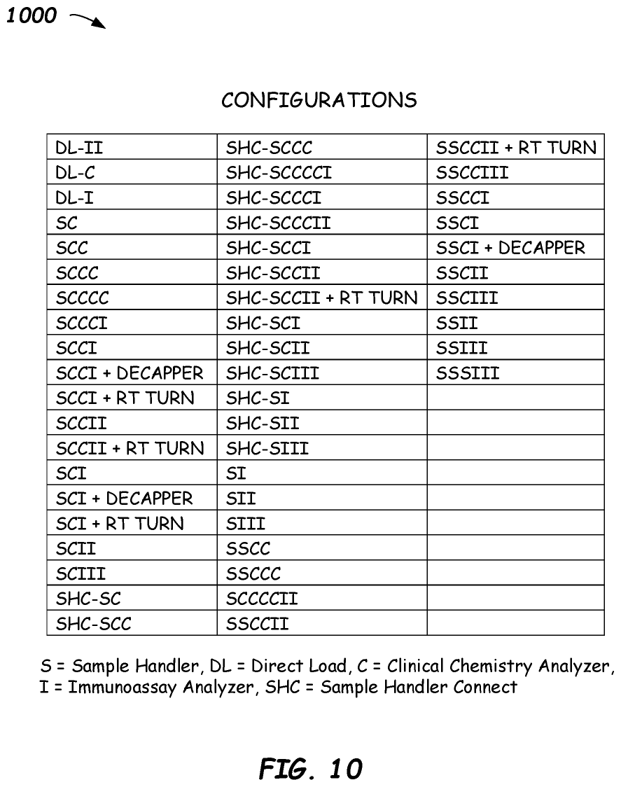

FIG. 10 illustrates an example set 1000 of predefined physical layouts for an automated laboratory diagnostic system that may be input to layout program 710. In the embodiment shown, 50 pre-defined physical layouts are included in the example set 1000. Fewer or more pre-defined physical layouts may be included. Any suitable format and/or nomenclature recognizable by the layout program 710 may be used to describe a set of pre-defined physical layouts. Such format/nomenclature may indicate for each pre-defined physical layout the modules included (and thus the functions performed) and the manner in which the modules are connected via the sample transport system. The format/nomenclature may also indicate the footprint area, shape, and/or dimensions of each pre-defined physical layout. Alternatively, in some embodiments, the layout program 710 may determine the function(s) performed by the modules, calculate areas/dimensions, and/or obtain other information related thereto based on data stored in the database 610.

Returning again to FIG. 7, the tentative physical layout from the layout program 710 is input to the simulation program 712. The simulation program 712 also receives as input a representative subset of the sample tests/analyses to be performed by the proposed automated laboratory diagnostic system (i.e., the system having its physical layout generated). In those systems with a small menu of tests/analyses to be performed, all such tests/analyses may be provided as input to the simulation program 712. The simulation program 712 also receives one or more objectives to be achieved by the physical layout of the system. The objectives may relate to, e.g., performance, costs, operating parameters (e.g., total heat generated based on the number of samples processed per module per unit of time), etc., as described in more detail below. The objectives may also be prioritized and/or weighted. The simulation results of the sample tests/analyses are then evaluated against the objectives at decision block 714.

The system objectives may include various performance criteria, such as, e.g., sample throughput (e.g., the total number of samples to be processed per 8-hour shift, per day, per week, etc.); sample turn-around-time (e.g., individual sample processing rate); one or more minimum and/or maximum processing times for the testing/analysis of certain types of samples (e.g., blood, urine, etc.); one or more minimum and/or maximum processing times for performing one or more particular types of tests/analyses, one or more minimum and/or maximum processing times for moving a sample from one location to another location; etc.

The system objectives may additionally or alternatively include various cost goals, such as, e.g., system purchase cost, maintenance costs, utility costs, supply costs (e.g., reagent additives, cuvettes, and aspirating/dispensing probes), etc.

In some embodiments, the objectives may additionally or alternatively include operating parameter limits related to module and track maintenance (e.g., based on usage), module calibration and quality control (e.g., also based on usage), and the environment of the system including, e.g., temperature, humidity, and/or vibration limits.

For the blank canvas embodiments, simulation results that do not meet one or more objectives (or do not come within a pre-determined acceptable range thereof) may indicate that the tentative physical layout is not considered optimized, and the layout generator software 708 returns to the layout program 710 for modification of the tentative physical layout based on the requirements and the simulation results. For example, simulation results may be employed to modify (e.g., train) the policy of the RL agent. This may include mapping simulation results (e.g., key performance indicators (KPIs)) to a reward value that is fed into the employed policy training scheme. For example, if the tentative physical layout is close to an optimized solution (e.g., one or more system objectives, such as one or more KPIs, are nearly met), the reward value is made high (e.g., a large positive value) so that few changes are made to the tentative physical layout. However, if the tentative physical layout is far from optimized (e.g., the tentative physical layout is not close to meeting the system objectives), the reward value is made small or negative so as to encourage large changes to the tentative physical layout.

For the pre-defined layout embodiments, simulation results that do not meet one or more objectives (or do not come within a pre-determined acceptable range thereof) may similarly indicate that the selected tentative physical layout is not considered optimized, and the software returns to the layout program 710 for selection of another pre-defined physical layout based on the system requirements and the simulation results. As with the black canvas example above, simulation results may be employed to modify (e.g., train) the policy of an RL agent, such as by mapping simulation results to a reward value that is fed into the employed policy training scheme. However, unlike with the blank canvas embodiment, the next tentative physical layout selected must be one of the pre-defined physical layouts (e.g., the predefined physical layout closest to the modified physical layout predicted through use of the RL agent and trained policy). (Similarly, an evolutionary algorithm may be employed to mutate the current physical layout (on which simulations were run) into another pre-defined physical layout as described further below.)

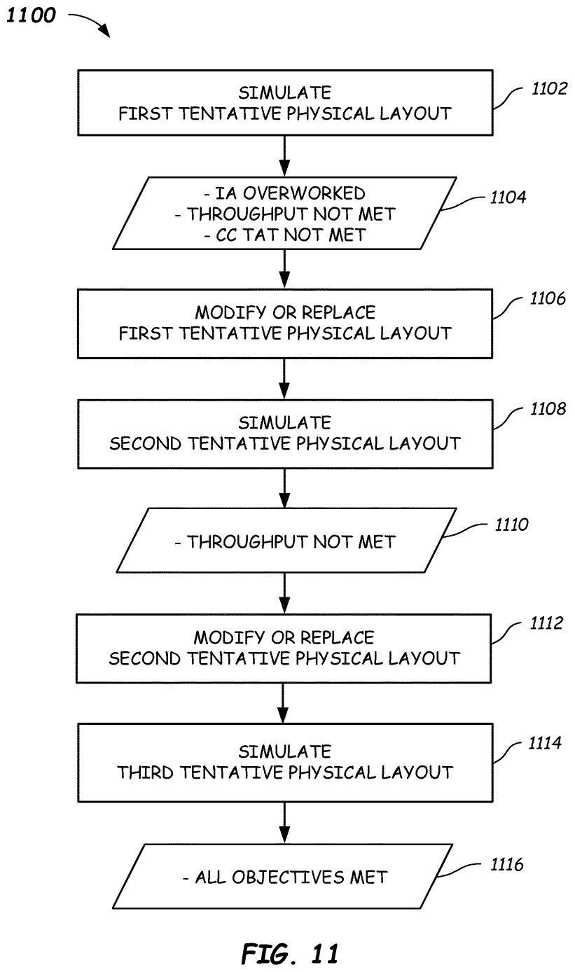

FIG. 11 illustrates an example of an optimization process 1100 of the layout generator software 708 (FIG. 7) for optimizing a tentative physical layout according to one or more embodiments. In some embodiments, the layout generator software 708 may employ an evolutionary algorithm in the optimization process 1100.

At process block 1102, the simulation program 712 simulates sample testing on a first tentative physical layout received from the layout program 710. The first tentative physical layout may have been generated by layout program 710 from a “blank canvas” or may be a least complex layout (or other layout) selected by layout program 710 from a set of pre-defined physical layouts received as input by the layout program 710.

The simulation results from process block 1102 are shown in data block 1104 and may indicate, in this example, that an immunoassay analyzer (IA) module is overworked, a sample throughput objective has not been met, and sample turn-around-time (TAT) for a clinical chemical (CC) analysis has not been met. These results indicate that the first tentative physical layout is not optimized.

In response to the simulation results, the layout generator software 708 returns to the layout program 710 from the “NO” branch of the decision block 714 (see FIG. 7) wherein the simulation results are analyzed (via, e.g., an evolutionary algorithm employed in the layout program 710), and the first tentative embodiment is modified or replaced at process block 1106 as follows: In the blank canvas embodiment, the layout program 710 may modify the first tentative physical layout based on the requirements, the simulation results, and any relevant data stored in database 610 (FIG. 6). For example, the layout program 710 may add another immunoassay analyzer (IA) module to overcome the overworked and throughput issues and may re-position a clinical chemical (CC) analyzer module closer to an input/output sampler handler module to the reduce turn-around-time (TAT). In the pre-defined layout embodiment, the layout program 710 may select another pre-defined physical layout (e.g., a next least complex physical layout or another predefined physical layout) from the set of pre-defined physical layouts based on the requirements, the simulation results, and any relevant data stored in database 610 (FIG. 6).

In an alternative pre-defined layout embodiment, the layout program 710 employing an evolutionary algorithm may modify (instead of replace) the first tentative physical layout in a same or similar manner as in the blank canvas embodiment. For example, an evolutionary algorithm may be employed that initially starts with a first laboratory configuration, such as a simple diagnostic laboratory configuration (e.g., sample handler +clinical chemistry analyzer +immunoassay analyzer (SCI) in FIG. 10) as the first tentative physical layout. Based on the simulation results for the first tentative physical layout, an “offspring” of the first tentative physical layout may be selected (e.g., SCII, SCCI, SHC-SCI, etc.). In this case, since a discrete set of options are available, the decision variables are limited (e.g., to the number of sample handlers (S), clinical chemistry analyzers (C), immunoassay analyzers (I), etc., employed within the physical layout). For example, consider a situation where a customer wants to purchase a laboratory diagnostic system and is deciding on the particular configuration to employ. A first example constraint for the diagnostic laboratory system is area of the laboratory. Assuming this constraint is met, another constraint may be the required throughput or minimizing costs for the customer.

Based on simulation results of an initial (tentative) physical layout for the laboratory system, an evolutionary algorithm may determine changes or “mutations” to make to the initial physical layout. Additionally, “crossovers” may be employed to extract useful configuration components from multiple “parent” configurations. Mutations and crossovers result in “offspring” that may be evaluated via simulations. Offspring that show improvements are further mutated (if needed) while offspring that do not show improvements may be discarded. For example, if a simulation indicates (e.g., such as via one or more key performance indicators (KPIs) or other laboratory objectives) that a particular chemical analyzer is being overworked, one mutation may be to add another, duplicate chemical analyzer to the existing configuration. Selection may involve running a simulation to see if laboratory objectives are met, while also validating that the proposed physical layout (generated by a mutation or crossover) is one of the available pre-defined physical layouts. For example, if the initial (tentative) physical layout is SCI, three “viable” mutations may be SCII, SSCII, and SSII as these configurations are available predefined physical layout configurations (see FIG. 10).

Upon completion of the layout modifications or selection of another pre-defined physical layout, the layout program 710 outputs a second tentative physical layout.

At process block 1108, the simulation program 712 simulates the sample testing on the second tentative physical layout received from layout program 710.

The simulation results from process block 1108 are shown in data block 1110 and may indicate, again in this example, that the sample throughput objective is still not met, indicating that the second tentative physical layout is also not optimized.

In response thereto, the layout generator software 708 again returns to the layout program 710 wherein, at process block 1112, the layout program 710 may, for the blank canvas and the alternative pre-defined layout embodiments, modify the second tentative physical layout to include, e.g., additional parallel track segments to alleviate sample transport bottlenecks and traffic jams that may be causing the layout to not meet the throughput objective. For the predefined layout embodiment, the layout program 710 may again select a different pre-defined layout (e.g., a next least complex layout or other suitable pre-defined layout) from the set of pre-defined physical layouts based on the requirements, the latest simulation results, and any relevant data stored in database 610 (FIG. 6). Upon completion of the layout modifications or selection of another pre-defined physical layout, the layout program 710 outputs a third tentative physical layout at process block 1112.

At process block 1114, the simulation program 712 simulates sample testing on the third tentative physical layout received from layout program 710.

In response to the simulation results from process block 1114 meeting the objectives (in this example), as shown in data block 1116, the simulated tentative physical layout is considered optimized at decision block 714 (FIG. 7) and is output at output block 716 as the final physical layout.

In response to the simulation results from process block 1114 not meeting the objectives, the optimization process 1100 may continue for a pre-determined period of time or a pre-determined number of tentative physical layouts, wherein if none of the simulated tentative physical layouts are able to meet all of the objectives, the layout generator software 708 may stop executing the optimization process 1100. In this case, one or more of the tentative physical layouts meeting most of the objectives or coming closest to meeting some or all of the objectives (wherein one or more of the objectives may have been prioritized and/or weighted and provided as input to the simulation program 712) may be output at output block 716 (see FIG. 7) as one or more final physical layouts along with their respective simulation results.

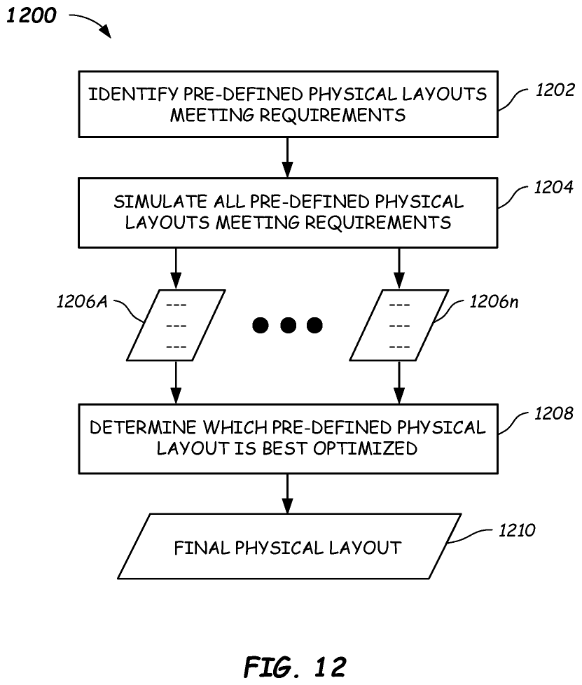

FIG. 12 illustrates an alternative optimization process 1200 of the layout generator software 708 (FIG. 7) for optimizing a tentative physical layout according to one or more pre-defined layout embodiments having a small number of pre-defined physical layouts (e.g., 10 or less). The layout program 710 of the layout generator software 708 may first determine, at process block 1202, which one or more of the pre-defined physical layouts meet the system requirements. The simulation program 712, which in some embodiments may be based on a standard discrete-event simulator (such as Emulate3D by Rockwell Automation, Inc. of Milwaukee, WI), may then simulate at process block 1204 sample testing on all the pre-defined physical layouts determined to meet the system requirements. The simulation results shown in data blocks 1206 to 1206n may then be analyzed at process block 1208 to determine a best optimized physical layout based on the system requirements and objectives (wherein some or all of the objectives may be prioritized or weighted). The determination at process block 1208 may be performed by the simulation program 712 or another software entity of the layout generator software 708. The best optimized physical layout determined at process block 1208 may then be output as a final physical layout as shown in data block 1210 (and as shown at output block 716 of FIG. 7).

In an alternative blank canvas embodiment of the optimization process 1100 of the layout generator software 708, portions of a physical layout may be placed by the layout program 710 and then simulated by the simulation program 712 based on specific sample tests and objectives related to that portion. Upon that portion successfully meeting its objectives, this alternative optimization process returns to the layout program 710 to place another portion of the tentative layout, which is then simulated by the simulation program 712. Referring to FIG. 8, this alternative optimization process (employing, e.g., an RL algorithm) may proceed as follows:
Iteration 0: Initialize with a blank canvas 802;
Iteration 1: RL agent runs simulation, places SH and analyzer module A1 connected by straight segment 804;
Iteration 2: RL agent runs simulation, places additional analyzer module A2 with straight segments 806 and 807;
Iteration 3: RL agent runs simulation, adds intersection segments 809 and 810;
Iteration N: process continues until all modules and sample transport system components placed and simulation results indicate all objectives met (or as best met) as described above, wherein layout modifications may be made as described above in response to objectives not being met.

The output of the final physical layout may include, e.g., a detailed scaled drawing of the modules and sample transport system, a listing of a physical location of each module (given in terms of, e.g., a suitable/generic coordinate system), a physical location and identification of each track segment of the sample transport system (also given in terms of, e.g., a suitable/generic coordinate system), connectivity between the track segments (identifying locations where, e.g., multiple track segments may be connected by a sample container robot handler), interaction points between the modules and the sample transport system (e.g., track connections and/or sample container robot handler locations); and/or a maximum number of sample carriers that can be concurrently and safely handled by the sample transport system. Other information may alternatively or additionally be included in or with the output of the final physical layout.

Advantageously, the layout generator software 608/708 can scale. That is, the layout generator software 608/708—supported by sufficient module and sample transport system data in database 610—may be operative to generate physical layouts for automated laboratory diagnostic systems of various sizes and/or complexities.

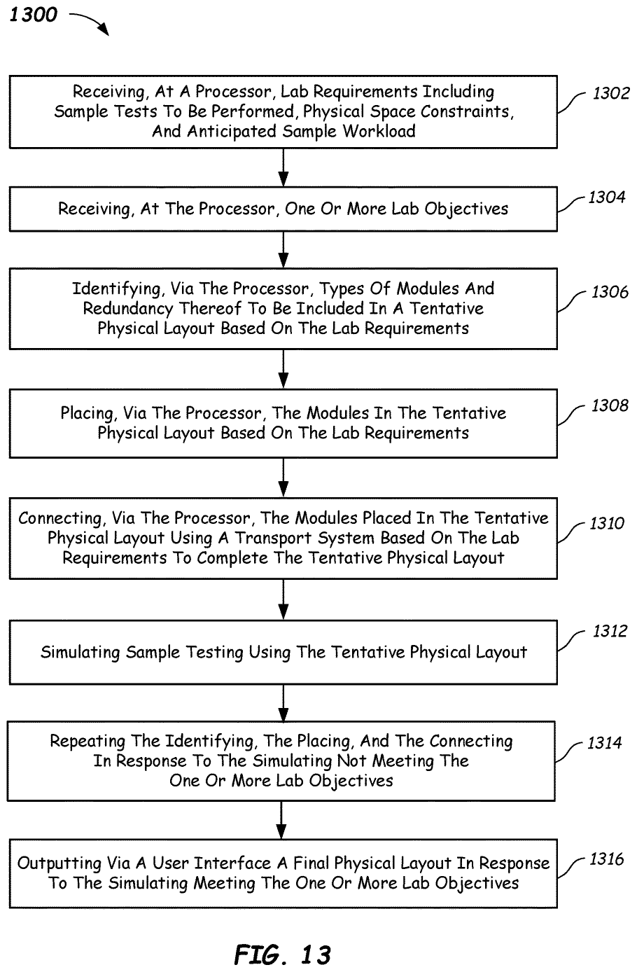

FIG. 13 illustrates a flowchart of a method 1300 of generating a physical layout of an automated laboratory diagnostic system according to one or more embodiments. The method 1300 includes, at process block 1302, receiving, at a processor executing layout generator software, laboratory requirements including sample tests to be performed, physical space constraints, and anticipated sample workload. For example, this information may be provided by an operator to processor 602 for use with layout generator software 708.

At process block 1304, the method 1300 includes receiving, at the processor executing the layout generator software, one or more laboratory objectives.

At process block 1306, the method 1300 includes identifying, via the processor executing the layout generator software, particular types of modules and redundancy thereof to be included in a tentative physical layout based on the laboratory requirements.

The method 1300 includes, at process block 1308, placing, via the processor executing the layout generator software, the particular modules in the tentative physical layout based on the laboratory requirements.

The method 1300 includes, at process block 1310, connecting, via the processor executing the layout generator software, the particular modules placed in the tentative physical layout using a sample transport system based on the laboratory requirements to complete the tentative physical layout.

At process block 1312, the method 1300 includes simulating sample testing using the tentative physical layout. For example, simulation program 712 may be employed to simulate sample testing using the tentative physical layout. As stated, simulation program 712 may be executed by processor 602 or a different computing resource.

At process block 1314, the method 1300 includes repeating the identifying, the placing, and the connecting in response to the simulating not meeting the one or more laboratory objectives. In general, the tentative physical layout may be modified repeatedly until one or more laboratory objectives have been met (or until it is determined that the desired objectives cannot be met). For example, process block 1306 (identifying types of modules and redundancy to be included), process block 1308 (placing modules based on lab requirements), process block 1310 (connecting modules in the tentative physical layout using a transport system), and process block 1312 (simulating sample testing using the tentative physical layout) may be repeated 1, 2, 5, 10, 20, 50 or more times until one or more laboratory objectives have been met. In some embodiments, if laboratory objectives are not met within a predetermined number of iterations and/or a predetermined time period, the operator may be notified of which objectives cannot be met and provided with the physical layout that comes closest to meeting those objectives. The method 1300 may then terminate.

If the one or more laboratory objectives have been met, at process block 1316, the method 1300 includes outputting, via a user interface coupled to the processor, a final physical layout in response to the simulating meeting the one or more laboratory objectives.

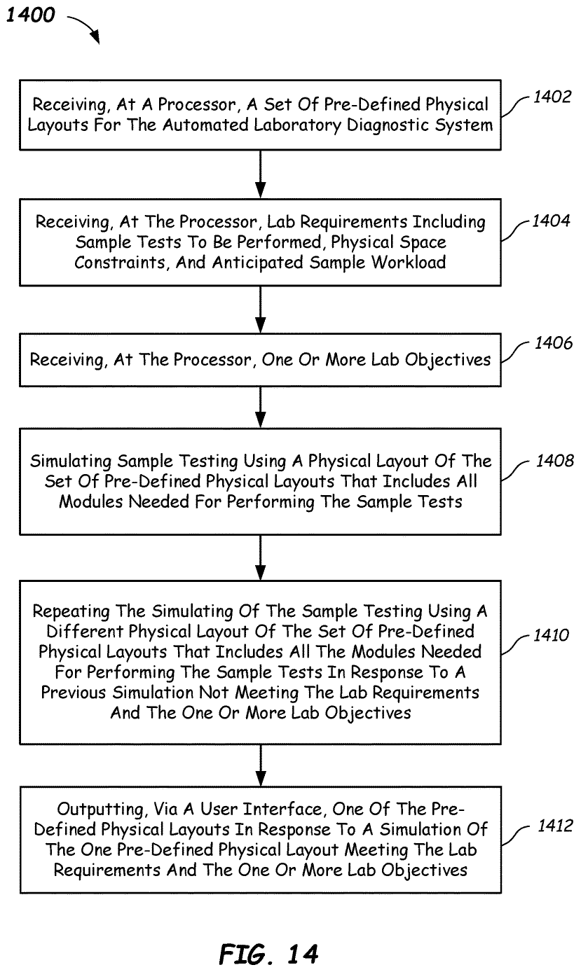

FIG. 14 illustrates a flowchart of another method 1400 of generating a physical layout of an automated laboratory diagnostic system according to one or more embodiments. The method 1400 includes, at process block 1402, receiving, at a processor executing layout generator software, a set of pre-defined physical layouts for the automated laboratory diagnostic system. For example, a set of predefined physical layouts, such as set 1000 of FIG. 10 or another pre-defined physical layout set, may be provided (e.g., from database 610) to processor 602 for use with layout generator software 708.

At process block 1404, the method 1400 includes receiving, at the processor executing layout generator software, laboratory requirements including sample tests to be performed, physical space constraints, and anticipated sample workload. For example, this information may be provided by an operator to processor 602 for use with layout generator software 708.

At process block 1406, the method 1400 includes receiving, at the processor executing layout generator software, one or more laboratory objectives. An operator may provide the one or more laboratory objectives, for example.

The method 1400 includes, at process block 1408, simulating sample testing using a physical layout of the set of the pre-defined physical layouts that includes all modules needed for performing the sample tests (which in some embodiments may be the least complex physical layout). For example, simulation program 712 may be employed to simulate sample testing using the tentative physical layout.

The method 1400 includes, at process block 1410, repeating the simulating of the sample testing using a different physical layout of the set of the pre-defined physical layouts that includes all modules needed for performing the sample tests in response to a previous simulation not meeting the laboratory requirements and the one or more laboratory objectives. In some embodiments, the different physical layout may be a next least complex physical layout or a physical layout determined using an RL or evolutionary algorithm as previously described. In general, simulating of different pre-defined physical layouts may continue until the one or more laboratory objectives have been met (or until it is determined that the desired objectives cannot be met). For example, process block 1408 may be repeated for different pre-defined physical layouts until the one or more laboratory objectives have been met. In some embodiments, if no pre-defined physical layout meets the one or more laboratory objectives then method 1400 may terminate.

Assuming one of the pre-defined physical layouts meets the one or more laboratory objectives, in process block 1412, the method 1400 includes outputting, via a user interface coupled to the processor, one of the pre-defined physical layouts in response to a simulation of the one predefined physical layout meeting the laboratory requirements and the one or more laboratory objectives.

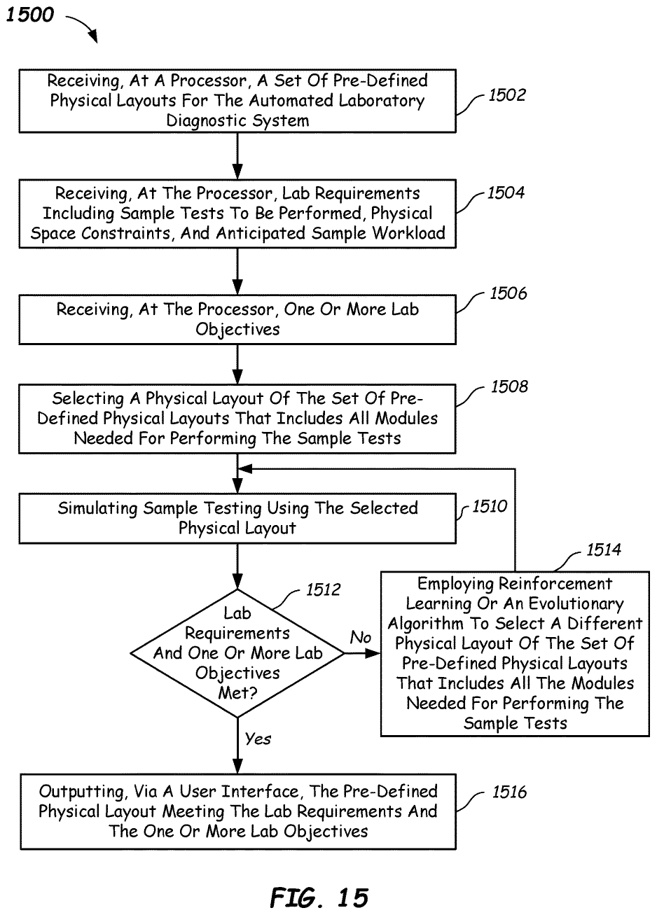

FIG. 15 illustrates a flowchart of another method 1500 of generating a physical layout of an automated laboratory diagnostic system according to one or more embodiments. The method 1500 includes, at process block 1502, receiving, at a processor executing layout generator software, a set of pre-defined physical layouts for the automated laboratory diagnostic system. For example, a set of predefined physical layouts, such as set 1000 of FIG. 10 or another pre-defined physical layout set, may be provided (e.g., from database 610) to processor 602 for use with layout generator software 708.

At process block 1504, the method 1500 includes receiving, at the processor executing layout generator software, laboratory requirements including sample tests to be performed, physical space constraints, and anticipated sample workload. For example, this information may be provided by an operator to processor 602 for use with layout generator software 708.

At process block 1506, the method 1500 includes receiving, at the processor executing layout generator software, one or more laboratory objectives. An operator may provide the one or more laboratory objectives, for example.

The method 1500 includes, at process block 1508, selecting a physical layout of the set of pre-defined physical layouts that includes all modules needed for performing the sample tests. In some embodiments, the selected physical layout may be the least complex physical layout.

The method 1500 includes, at process block 1510, simulating sample testing using the selected physical layout. For example, simulation program 712 may be employed to simulate sample testing using the selected physical layout.

The method 1500 includes, at decision block 1512, determining whether the simulation met the laboratory requirements and the one or more laboratory objectives.

If, in decision block 1512, it is determined that the simulation did not meet the laboratory requirements and the one or more laboratory objects, in process block 1514, reinforcement learning or an evolutionary algorithm is employed to select a different physical layout of the set of pre-defined physical layouts that includes all the modules needed for performing the sample tests and the simulating (at process block 1510) is repeated. In some embodiments, the different physical layout may be the next least complex physical layout. In general, simulating of different predefined physical layouts may continue until the one or more laboratory objectives have been met (or until it is determined that the desired objectives cannot be met). For example, process block 1514 and process block 1510 may be repeated for different pre-defined physical layouts until the one or more laboratory objectives have been met. In some embodiments, if no pre-defined physical layout meets the one or more laboratory objectives then method 1500 may terminate.

Assuming one of the pre-defined physical layouts meets the one or more laboratory objectives, in process block 1516, the method 1500 includes outputting, via a user interface coupled to the processor, the pre-defined physical layout meeting the laboratory requirements and the one or more laboratory objectives.

As described above, numerous factors may be considered as part of the physical layout optimization process. For example, physical space constraints to be considered may include at least one of available floor space, power source availability and location, user access to modules, temperature requirements, humidity requirements, security requirements, and biosafety requirements. Likewise, example laboratory objectives to be considered may include at least one of sample throughput, sample turn-around-time, hardware costs, operating costs, supply costs, reagent replacement rates, load balancing of the modules, fault tolerance, and a weighted combination of any thereof. Fault tolerance considerations may include design choices that address robustness to failures, such as when a section or segment of a travel path becomes unusable due to service maintenance, analyzer downtime during replacement of consumables/reagents or other servicing, etc. Other considerations may include assay menus for the physical layout, pre- and post-processing module requirements, operator/maintenance access, or the like. One or more of these factors may be considerations used during reinforcement learning or evolutionary algorithm implementations as described herein.

In at least some embodiments, the optimized physical layout determined via one or more of the methods described herein may include the modules/analyzers to be deployed (e.g., which pre- or post-processing modules, which analyzers, how many modules/analyzers, how each module or analyzer may be loaded/prepared, track connections between modules/analyzers, or the like).

As a further example of application of reinforcement learning to physical layout selection, in some embodiments, the reward function employed may be shaped by factors including key performance indicators (KPIs) such as TAT/Throughput. The reward function may run a simulation of the worklist on the tentative physical layout to determine whether the throughput/TAT requirements are met. In general, while throughput/TAT is a common KPI to optimize, this reward function may also include other factors (e.g., reagent replacement rates, quality control calibrations needed, etc.) that may be weighted according to customer requirements.

In some embodiments, training may be performed iteratively, and agents may be trained for many “episodes”. Each episode may start with a random set of worklists/constraints for which the agent iteratively designs a physical layout while updating policy weights using the reward function. An episode may be considered complete, for example, when the designed physical layout meets the constraints and requirements, or after a certain timeout (e.g., the agent is unable to find a suitable physical layout within a predetermined amount of time). Eventually, with sufficient training, an agent may begin designing suitable physical layouts within a few iterations (e.g., episode lengths reduce), which identifies when training has converged. Once training has converged, the neural network underlying the policy may be fixed (e.g., weights/parameters are unchanged). Multiple iterations on a set of laboratory constraints/requirements may be executed until the layout program 710 produces a suitable physical layout. This may be equivalent to running just one episode of training except that no weight updates are made to the RL agent policy. The “environment” used may still be the same one used during training and the same observations from the environment may be used to feed into the RL agent.

One or more of the methods described herein may be implemented in computer program code, such as part of an application (or other executable instructions) executable on a computer, as one or more computer program products. Other systems, methods, computer program products and data structures also may be provided. Each computer program product described herein may be carried by a non-transitory medium readable by a computer (e.g., a DVD, a hard drive, a random-access memory, etc.).

While the disclosure is susceptible to various modifications and alternative forms, specific method and apparatus embodiments have been shown by way of example in the drawings and are described in detail herein. It should be understood, however, that the particular methods and apparatus disclosed herein are not intended to limit the disclosure, which is defined by the following claims.

What is claimed is:

1. A method of generating a physical layout of an automated laboratory diagnostic system, comprising:
receiving, at a processor executing layout generator software, laboratory requirements including sample tests to be performed, physical space constraints, and anticipated sample workload;
receiving, at the processor executing the layout generator software, one or more laboratory objectives;
identifying, via the processor executing the layout generator software, particular types of modules and redundancy thereof to be included in a tentative physical layout based on the laboratory requirements;
placing, via the processor executing the layout generator software, the particular modules in the tentative physical layout based on the laboratory requirements;
connecting, via the processor executing the layout generator software, the particular modules placed in the tentative physical layout using a sample transport system based on the laboratory requirements to complete the tentative physical layout;
simulating sample testing using the tentative physical layout;
repeating the identifying, the placing, and the connecting in response to the simulating not meeting the one or more laboratory objectives; and
outputting, via a user interface coupled to the processor, a final physical layout in response to the simulating meeting the one or more laboratory objectives.

2. The method of claim 1, wherein the final physical layout comprises at least some of:
a physical location of each module;
a physical location of each track segment of the sample transport system;
connectivity between the track segments;
module interaction points with the sample transport system; and
a maximum number of sample carriers handled by the sample transport system.

3. The method of claim 1, wherein the sample transport system includes track segments for moving sample carriers, track switches, and sample container robot handlers.

4. The method of claim 1, wherein the modules include at least one of a clinical chemistry analyzer, an immunoassay analyzer, and a molecular testing analyzer.

5. The method of claim 1, wherein the modules include at least one of a pre-processing module and a post-processing module.

6. The method of claim 1, wherein prior to the outputting, the method further comprises adding to, subtracting from, re-positioning, or re-connecting one or more modules in the tentative physical layout in response to the repeating the identifying, the placing, and the connecting.

7. The method of claim 1, wherein the layout generator software comprises a trained reinforcement learning (RL) algorithm.

8. The method of claim 1 wherein the physical space constraints include at least one of available floor space, power source availability and location, user access to modules, temperature requirements, humidity requirements, security requirements, and biosafety requirements.

9. The method of claim 1 wherein the one or more laboratory objectives include at least one of sample throughput, sample turn-around-time, hardware costs, operating costs, supply costs, reagent replacement rates, load balancing of the modules, fault tolerance, and a weighted combination of any thereof.

10. A system for generating a physical layout of an automated laboratory diagnostic system, comprising:
a computer including a processor, a memory, and a user interface, the memory storing layout generator software, wherein the processor executing the layout generator software is operative to:
receive laboratory requirements including sample tests to be performed, physical space constraints, and anticipated sample workload;
receive one or more laboratory objectives;
identify particular types of modules and redundancy thereof to be included in a tentative physical layout based on the laboratory requirements;
place the particular modules in the tentative physical layout based on the laboratory requirements;
connect the particular modules placed in the tentative physical layout using a sample transport system based on the laboratory requirements to complete the tentative physical layout;
simulate sample testing using the tentative physical layout;
repeat the identify, the place, and the connect in response to a simulation of a subset of the tests executed on the tentative physical layout not meeting the one or more laboratory objectives; and
output via the user interface a final physical layout in response to a simulation meeting the one or more laboratory objectives.

11. The system of claim 10, wherein the final physical layout comprises at least some of:
a physical location of each module;
a physical location of each track segment of the sample transport system;
connectivity between the track segments;
module interaction points with the sample transport system; and
a maximum number of sample carriers handled by the sample transport system.

12. The system of claim 10, wherein the processor executing the layout generator software is further operative to:
add to, subtract from, re-position, or re-connect one or more modules in the tentative physical layout in response to repeating the identify, the place, and the connect.

13. The system of claim 10, wherein the layout generator software comprises a trained reinforcement learning (RL) algorithm.

14. The system of claim 10 wherein the physical space constraints include at least one of available floor space, power source availability and location, user access to modules, temperature requirements, humidity requirements, security requirements, and biosafety requirements.

15. The system of claim 10 wherein the one or more laboratory objectives include at least one of sample throughput, sample turn-around-time, hardware costs, operating costs, supply costs, reagent replacement rates, load balancing of the modules, fault tolerance, and a weighted combination of any thereof.

16. A method of generating a physical layout of an automated laboratory diagnostic system, comprising:
receiving, at a processor executing layout generator software, a set of pre-defined physical layouts for the automated laboratory diagnostic system;
receiving, at the processor executing layout generator software, laboratory requirements including sample tests to be performed, physical space constraints, and anticipated sample workload;
receiving, at the processor executing layout generator software, one or more laboratory objectives;
simulating sample testing using a physical layout of the set of the pre-defined physical layouts that includes all modules needed for performing the sample tests;
repeating the simulating of the sample testing using a different physical layout of the set of the pre-defined physical layouts that includes all modules needed for performing the sample tests in response to a previous simulation not meeting the laboratory requirements and the one or more laboratory objectives; and
outputting, via a user interface coupled to the processor, one of the pre-defined physical layouts in response to a simulation of the one pre-defined physical layout meeting the laboratory requirements and the one or more laboratory objectives.

17. The method of claim 16, wherein each of the pre-defined physical layouts includes at least one pre-processing module, at least one analyzer module, and at least one post-processing module.

18. The method of claim 16, wherein the one pre-defined physical layout comprises at least some of:
a physical location of each module;
a physical location of each track segment of a sample transport system;
connectivity between the track segments;
module interaction points with the sample transport system; and
a maximum number of sample carriers handled by the sample transport system.

19. The method of claim 16 wherein the physical space constraints include at least one of available floor space, power source availability and location, user access to modules, temperature requirements, humidity requirements, security requirements, and biosafety requirements.

20. The method of claim 16 wherein the one or more laboratory objectives include at least one of sample throughput, sample turn-around-time, hardware costs, operating costs, supply costs, reagent replacement rates, load balancing of modules, fault tolerance, and a weighted combination of any thereof.

21. A method of generating a physical layout of an automated laboratory diagnostic system, comprising:
receiving, at a processor executing layout generator software, a set of pre-defined physical layouts for the automated laboratory diagnostic system;
receiving, at the processor executing layout generator software, laboratory requirements including sample tests to be performed, physical space constraints, and anticipated sample workload;
receiving, at the processor executing layout generator software, one or more laboratory objectives;
selecting a physical layout of the set of predefined physical layouts that includes all modules needed for performing the sample tests;
simulating sample testing using the selected physical layout;
if the laboratory requirements and the one or more laboratory objectives are not met, employing reinforcement learning or an evolutionary algorithm to select a different physical layout of the set of pre-defined physical layouts that includes all the modules needed for performing the sample tests and repeating the simulating; and
if the laboratory requirements and the one or more laboratory objectives are met with one of the pre-defined physical layouts, outputting, via a user interface coupled to the processor, the one pre-defined physical layout.

22. The method of claim 21, wherein each of the pre-defined physical layouts includes at least one pre-processing module, at least one analyzer module, and at least one post-processing module.

23. The method of claim 21, wherein the one pre-defined physical layout comprises at least some of:
a physical location of each module;
a physical location of each track segment of a sample transport system;
connectivity between the track segments;
module interaction points with the sample transport system; and
a maximum number of sample carriers handled by the sample transport system.

24. The method of claim 21 wherein the physical space constraints include at least one of available floor space, power source availability and location, user access to modules, temperature requirements, humidity requirements, security requirements, and biosafety requirements.

25. The method of claim 21 wherein the one or more laboratory objectives include at least one of sample throughput, sample turn-around-time, hardware costs, operating costs, supply costs, reagent replacement rates, load balancing of modules, fault tolerance, and a weighted combination of any thereof.
